(19) United States
(12) Patent Application Publication
(10) Pub. No.: US 2013/0005079 A1
(43) Pub. Date: Jan. 3, 2013

(54) ORGANIC THIN FILM TRANSISTORS AND METHODS OF FORMING THE SAME

(75) Inventors: Yong-Young NOH, Daejeon (KR); In-Kyu You, Daejeon (KR); Jae Bon Koo, Daejeon (KR)

(73) Assignee: ELECTRONICS AND TELECOMMUNICATIONS RESEARCH INSTITUTE, Daejeon (KR)

(21) Appl. No.: 13/616,668

(22) Filed: Sep. 14, 2012

Related U.S. Application Data
(62) Division of application No. 12/510,847, filed on Jul. 28, 2009.

(30) Foreign Application Priority Data
Mar. 23, 2009 (KR) 10-2009-0024624

(51) Int. Cl. H01L 51/40

(52) U.S. Cl. 438/99; 257/E51.005

(57) ABSTRACT

Provided is an organic thin film transistor, method of forming the same, and a memory device employing the same. The organic thin film transistor includes a substrate, a source electrode and a drain electrode on the substrate, an active layer on the substrate between the source electrode and the drain electrode, a gate electrode controlling the active layer, and an organic dielectric layer between the active layer and the gate electrode. The organic dielectric layer includes nanoparticles, a hydrophilic polymer surrounding the nanoparticles, and a hydrophobic polymer.

### CROSS-REFERENCE TO RELATED APPLICATIONS

This is a divisional of co-pending U.S. application Ser. No. 12/510,847, filed Jul. 28, 2009. This U.S. non-provisional patent application also claims priorities under 35 U.S.C. §119 of Korean Patent Application No. 10-2009-0024624, filed on Mar. 23, 2009, the entire contents of which are hereby incorporated by reference.

### BACKGROUND

The present invention disclosed herein relates to a transistor and a method of forming the same, and more particularly, to an organic thin film transistor and a method of forming the same.

With the trend for increased multifunctional capability of electronic device, demand for memory devices suitable for such electronic devices is sharply increasing. Particularly, lightweight and inexpensive memory devices suitable for portable electronic equipment have recently become necessary.

In accordance with such requirements, memory devices with properties different from typical memory devices have been actively researched. For example, research on memory devices using organic material instead of inorganic material is actively being performed. Memory devices using organic material are advantageous because they can be formed of low cost material at a relatively low temperature.

### SUMMARY

The present invention provides an organic thin film transistor and a memory device including the organic thin film transistor with enhanced reliability.

The present invention also provides methods of manufacturing a organic thin film transistor and a memory device including the thin film transistor with enhanced process efficiency.

Embodiments of the present invention provide organic thin film transistors including: a substrate; a source electrode and a drain electrode on the substrate; an active layer on the substrate between the source electrode and the drain electrode; a gate electrode controlling the active layer; and an organic dielectric layer between the active layer and the gate electrode, wherein the organic dielectric layer includes nanoparticles, and diblock copolymers having hydrophilic polymers surrounding the nanoparticles and including hydrophilic groups, and hydrophobic polymers including hydrophobic groups.

In some embodiments, the hydrophilic polymers may be configured such that the hydrophilic groups are directed toward the nanoparticles.

In other embodiments, the nanoparticles may comprise a metal or a metal compound.

In still other embodiments, a plurality of the nanoparticles may compose a group, and a plurality of groups consisting of the nanoparticles may exit in the organic dielectric layer, wherein the groups consisting of the nanoparticles are spaced apart from each other in the organic dielectric layer.

In even other embodiments, the nanoparticles may be spaced apart from the active layer and the gate electrode.

In yet other embodiments, the hydrophilic polymers may have a permittivity higher than the hydrophobic polymers.

In other embodiments of the present invention, methods of manufacturing an organic thin film transistor, the methods may include: forming a source electrode and a drain electrode on a substrate; forming an active layer on the substrate between the source electrode and the drain electrode; forming a gate electrode on a surface of the active layer; and forming an organic dielectric layer between the active layer and the gate electrode, wherein the forming of the organic dielectric layer includes providing a composition for organic dielectric layer including a diblock copolymer composed of hydrophilic polymers with hydrophilic groups and hydrophobic polymers with hydrophobic groups.

In some embodiments, the composition for organic dielectric layer may include: nano-precursors adjacent to first groups selected from the hydrophilic groups and the hydrophobic groups of the diblock copolymer; and a solvent having affinity to second groups selected from the hydrophilic groups and the hydrophobic groups of the diblock copolymer.

In other embodiments, the first groups may be the hydrophilic groups and the second groups may be the hydrophobic groups.

In still other embodiments, the forming of the organic dielectric layer may further include oxidizing or reducing the nano-precursors.

In even other embodiments, the forming of the organic dielectric layer may include self-assembling of the hydrophilic polymers and the hydrophobic polymers of the diblock copolymer.

In yet other embodiments, the nano-precursors are surrounded by the self-assembled hydrophilic polymers.

In further embodiments, the forming of the organic dielectric layer may further include oxidizing or reducing the nano-precursor.

In still further embodiments, the concentration of the diblock copolymers in the composition for organic dielectric layer may be equal to or higher than the critical micelle concentration.

In even further embodiments, the hydrophilic polymers in the diblock copolymer may have a volume ratio equal to or more than 0.05 and equal to or less than 0.65.

In yet further embodiments, the forming of the organic dielectric layer may further include providing a temperature higher than the glass transition temperature to the composition for organic dielectric layer.

Embodiments of the present invention provide a memory device including a organic thin film transistor including: a substrate; a source electrode and a drain electrode on the substrate; an active layer on the substrate between the source electrode and the drain electrode; a gate electrode controlling the active layer; and an organic dielectric layer between the active layer and the gate electrode, wherein the organic dielectric layer has nanoparticles, hydrophilic polymers surrounding the nanoparticles and including hydrophilic groups, and hydrophobic polymers including hydrophobic groups.

### BRIEF DESCRIPTION OF THE FIGURES

The accompanying figures are included to provide a further understanding of the present invention, and are incorporated in and constitute a part of this specification. The drawings illustrate exemplary embodiments of the present invention and, together with the description, serve to explain principles of the present invention. In the figures:

FIGS. 1A and 1B are schematic views illustrating an organic thin film transistor and a structure of a dielectric layer according to an embodiment of the present invention;

FIG. 2 is a partial sectional view of an organic thin film transistor according to another embodiment of the present invention;

FIG. 3 is a partial sectional view of an organic thin film transistor according to a further another embodiment of the present invention;

FIG. 4 is a flow diagram for explaining a method of forming gate dielectric film including diblock copolymer and metal nanoparticles according to embodiments of the present invention; and

FIG. 5 is a graph for explaining effects according to embodiments of the present invention.

### DETAILED DESCRIPTION OF EMBODIMENTS

Preferred embodiments of the present invention will be described below in more detail with reference to the accompanying drawings. These embodiments are provided so that this disclosure will be thorough and complete and will fully convey the scope of the present invention to those skilled in the art, and should not be constructed as limited to the embodiments set forth herein. These embodiments may be embodied in different forms without departing from the spirit and scope of the present invention. The word ‘and/of’ means that one or more or a combination of relevant constituent elements is possible. It will be understood that when an element such as a layer, film, region, or substrate is referred to as being “on” another element, it can be directly on the other element or intervening elements may also be present. It will be understood that, although the terms first, second, etc. may be used herein to describe various elements, components, regions, layers and/or sections, these elements, components, regions, layers and/or sections should not be limited by these terms. In the drawings, the thicknesses of layers and regions are exaggerated for clarity.

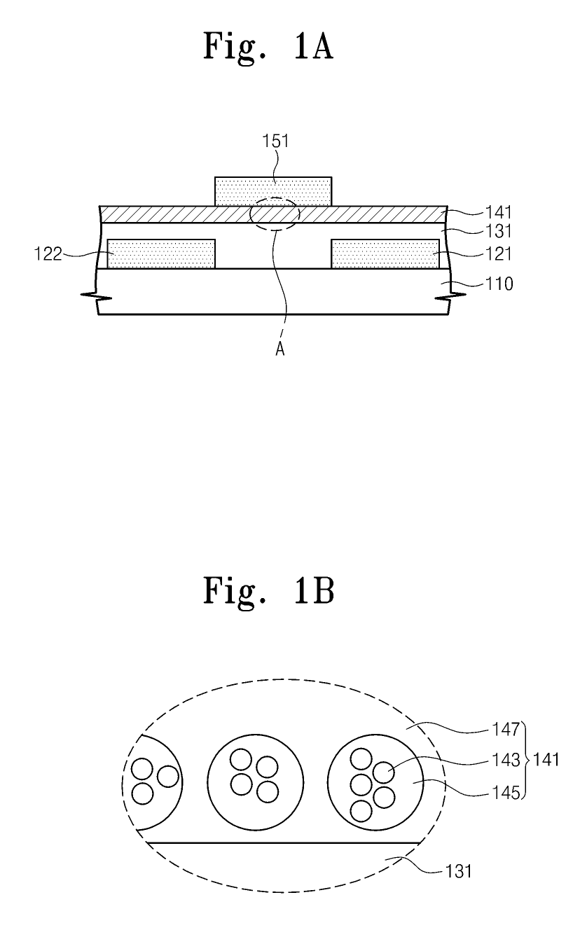

An organic thin film transistor according to an embodiment of the present invention will now be described with reference to FIGS. 1A and 1B. FIG. 1B is a detailed view of region ‘A’ shown in FIG. 1A. A source electrode 121 and a drain electrode 122 are disposed on a substrate 110. The substrate 110 may be, but is not limited to, a semiconductor substrate such as silicon wafer, a glass substrate, an organic substrate, or a plastic substrate. For example, the substrate 110 may include a semiconductor material, a doped semiconductor material, polyethersulphone, polyacrylate, polyetherimide, polyimide, or polyethyleneterepthalate. A top surface of the substrate 110 may be coated. For example, the substrate 110 may be coated with indium tin oxide (ITO).

The source electrode 121 and the drain electrode 122 may be formed spaced apart from each other. Each of the source electrode 121 and the drain electrode 122 may include a conductive material. The source electrode 121 and the drain electrode 122 may include a metal, a metal compound, or a conductive organic polymer. For example, the source electrode 121 and the drain electrode 122 may include at least one selected from the group consisting of, but are not limited to, gold (Au), silver (Ag), aluminum (Al), nickel (Ni), indium tin oxide (ITO), polyethylenedioxythiophene:polystyrene sulfonate (PEDOT:PSS), polyaniline and polypyrrole.

An active layer 131 may be disposed on the substrate 110. At least some of the active layer 131 may be disposed between the source electrode 121 and the drain electrode 122. Also, the active layer 131 may cover the source electrode 121 and the drain electrode 122. In operation of the organic thin film transistor, a channel may be formed in the active layer 131 between the source electrode 121 and the drain electrode 122.

The active layer 131 may include a semiconductor material. In an embodiment, the active layer 131 may include an organic semiconductor material. For example, the active layer 131 may include at least one selected from the group, but is not limited to, polythiophene and its derivatives, triisopropylsilyl (TIPS) pentacene and its derivatives, thienothiophene and its derivatives, pentacene precursor and its derivatives, α-6-thiophene and its derivatives, polyfluorene and its derivatives, pentacene and its derivatives, tetracene and its derivatives, anthracene and its derivatives, perylene and its derivatives, rubrene and its derivatives, cororene and its derivatives, phenylene tetracarboxylic diimide and its derivatives, polyparaphenylenevinylene and its derivatives, polythiophenevinylene and its derivatives, α-5-thiophene and its derivatives, oligothiophene and its derivatives, phthalocyanine and its derivatives, naphthalene tetra carboxylic acid diimide and its derivatives.

An organic dielectric layer 141 may be disposed on the active layer 131. The organic dielectric layer 141 may include a hydrophilic polymer 145 having at least one hydrophilic group and a hydrophobic polymer 147 having at least one hydrophobic group.

In an embodiment, one hydrophilic polymer and one hydrophobic polymer may constitute one diblock copolymer. Unlike this, two or more hydrophilic polymers and two or more hydrophobic polymers may constitute one diblock copolymer. At least two diblock copolymers may exist in the organic dielectric layer 141.

Nanoparticles 143 may be disposed at a region adjacent to the hydrophilic groups of the hydrophilic polymers 145 or at a region adjacent to the hydrophobic groups of the hydrophobic polymers 147. That is, the nanoparticles 143 may be surrounded by two or more hydrophilic polymers 145 or hydrophobic polymers 147. In an embodiment, the nanoparticles 143 may be surrounded by the hydrophilic polymers 145, as shown in FIG. 1B. The hydrophilic polymers 145 may be arranged such that the hydrophilic groups are directed toward the nanoparticles 143.

In an embodiment, a portion of the hydrophilic polymer 145 and a portion of the hydrophobic polymer 147 constitute the diblock copolymers. In the case where the hydrophilic polymer 145 and the hydrophobic polymer 147 constitute one diblock copolymer, the hydrophobic group of the hydrophobic polymer 147 and the hydrophilic group of the hydrophilic polymer 145 may be arranged to be directed toward an opposite direction to each other.

In another embodiment, the hydrophilic polymer 145 and the hydrophobic polymer 147 exist independently. In other words, two polymers, the hydrophilic polymer 145 and the hydrophobic polymer 147 do not constitute the diblock copolymer.

The nanoparticles 143 may include at least one selected from the group consisting of materials that can trap a charge. For example, the nanoparticle 143 may include at least one of metal and metal compound. Specifically, the nanoparticle 143 may include, but is not limited to, gold (Au), silver (Ag), copper (Cu), tungsten (W), cobalt (Co), iron oxide (FeO), hafnium oxynitride (HfON), tungsten oxide (WO), nickel oxide (NiO), barium titanate (BaTiO3) or strontium titanate (SrTiO3), and anything is possible if it can trap a charge and be formed in a nano-size.

A plurality of the hydrophobic polymers 147 may surround the hydrophilic polymers 145. Specifically, the diblock copolymers comprised of the hydrophilic polymers 145 and the hydrophobic polymers 147 may surround the nanoparticles 143, in which the diblock copolymers may be arranged such that the hydrophilic polymers 145 including the hydrophilic groups are directed toward the nanoparticles 143.

A plurality of nanoparticles 143 and two or more hydrophilic polymers 145 surrounding the plurality of the nanoparticles 143 may constitute one charge storage group. A plurality of the charge storage groups may be disposed in the organic dielectric layer 141. As aforementioned, since the nanoparticles 143 are surrounded by the hydrophilic polymers 145 and/or the hydrophobic polymers 147, the nanoparticles 143 may be spaced apart from the active layer 131 and/or gate electrode 151 to be described later. Accordingly, insulation characteristics of the organic dielectric layer 141 can be enhanced.

The charge storage group may have a configuration that is different from that shown in the drawings. For example, the charge storage group may be composed of the nanoparticles 143 arranged in a rod form, and the hydrophilic polymers of the diblock copolymers surrounding the nanoparticles 143. In other embodiments, the charge storage group may be composed of the nanoparticles 143 arranged in a plate form, and the hydrophilic polymers of the diblock copolymers surrounding the nanoparticles 143.

In an embodiment, the hydrophilic polymer 145 has a permittivity higher than the hydrophobic polymer 147. For example, the hydrophilic polymer 145 may be at least one selected from the group consisting of poly(4-vinyl phenol), poly(2-vinylpyridine), polyacrylonitrile, polychloroprene, poly(vinylidene fluoride) and poly(vinylidene chloride). Accordingly, insulation characteristics of the organic dielectric layer can be more enhanced.

In an embodiment, the hydrophobic polymer 147 has a permittivity higher than the hydrophilic polymer 145. For example, the hydrophobic polymer may include at least one selected from the group consisting of polybutadiene, polystyrene, polyisobutylene, poly(methyl methacrylate), polycarbonate, polychlorotrifluoroethylene, polyethylene, polypropylene, polytetrafluoroethylene (Teflon), CYTOP™, and polypropylene-co-butene.

A gate electrode 151 may be disposed on the organic dielectric layer 141. The gate electrode 151 may include a conductive material. The gate electrode 151 may include a metal, a metal compound or a conductive organic polymer. For example, the gate electrode 151 may include at least one selected from the group consisting of, but is not limited to, gold (Au), silver (Ag), aluminum (Al), nickel (Ni), indium tin oxide (ITO), polyethylenedioxythiophene:polystyrene sulfonate (PEDOT:PSS), polyaniline, and polypyrrole.

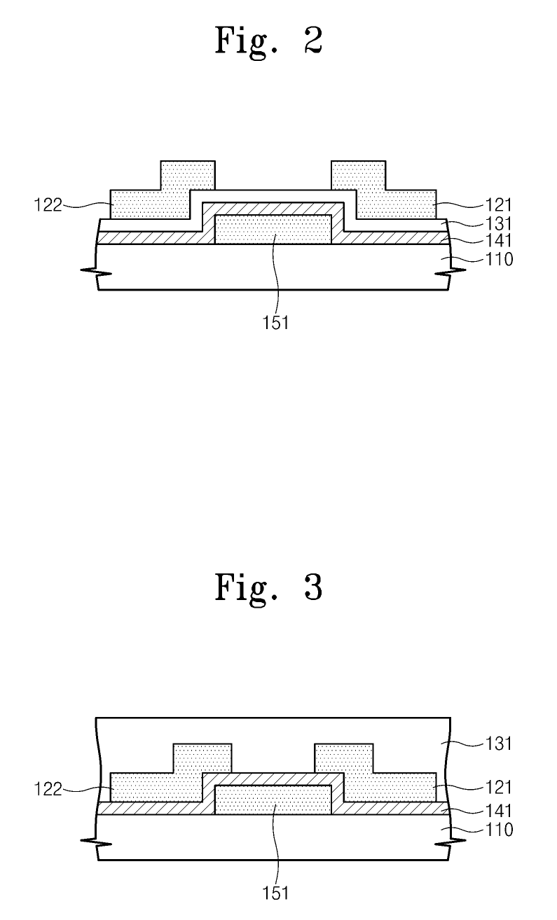

Referring to FIGS. 2 and 3, the substrate 110, the source electrode 121, the drain electrode 122, the active layer 131, the organic dielectric layer 141 and the gate electrode 151 may be arranged in a different configuration.

Referring to FIG. 2, the gate electrode 151 may be disposed on the substrate 110. The organic dielectric layer 141 may be disposed on the gate electrode 151. The organic dielectric layer 141 may cover a top surface of the gate electrode 151. Unlike in the drawing, the organic dielectric layer 141 may extend from the top surface of the gate electrode 151 and cover sidewalls of the gate electrode 151. As illustrated in FIG. 1, the organic dielectric layer 141 may include the hydrophilic polymers 145 surrounding the nanoparticles, and the hydrophobic polymers positioned at an edge of the organic dielectric layer 141.

The active layer 131 may be disposed on the organic dielectric layer 141. The source electrode 121 and the drain electrode 122 may be disposed on the active layer 131. The source electrode 121 and the drain electrode 122 may be spaced apart from each other. When a voltage is applied to the gate electrode 151, a channel may be formed in the active layer between the source electrode 121 and the drain electrode 122.

Referring to FIG. 3, unlike in FIG. 2, the active layer 131 may not be interposed between the organic dielectric layer 141 and the source and drain electrodes 121 and 122. In this case, the active layer 131 may be disposed between the source electrode 121 and the drain electrode 122 on the organic dielectric layer 141. As illustrated in FIG. 1, the organic dielectric layer 141 may include nanoparticles, hydrophilic polymers surrounding the nanoparticles, and hydrophobic polymers positioned at an edge of the organic dielectric layer 141.

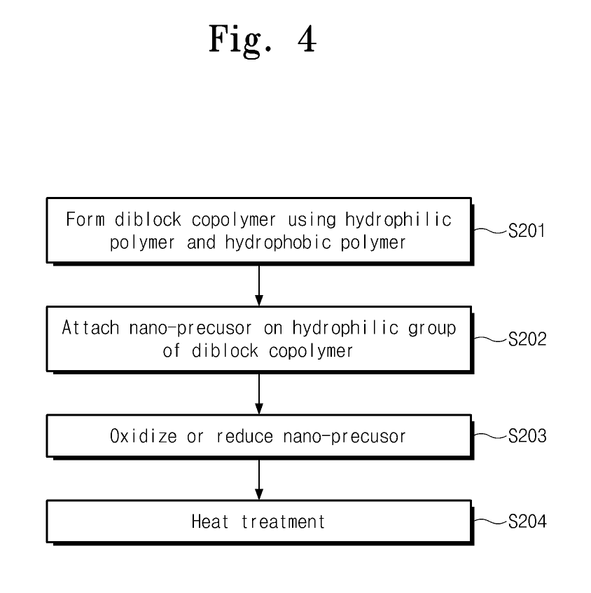

A method of forming an organic thin film transistor according to an embodiment of the present invention will now be described with reference to FIGS. 1A, 1B and 4. FIG. 4 is a flowchart illustrating a method of forming the organic dielectric layer of FIGS. 1A and 1B. In the following descriptions, a repetitive description for the same elements as those of the previous embodiment will be omitted.

Referring to FIG. 1A, the source electrode 121 and the drain electrode 122 may be formed on the substrate 110. The source electrode 121 and the drain electrode 122 may be formed by depositing a conductive layer on the substrate 110 and then patterning the deposited conductive layer. Unlike this, the source electrode 121 and the drain electrode 122 may be formed through an inkjet printing using a conductive ink.

The active layer 131 may be formed on the substrate 110. The active layer 131 may be formed between the source electrode 121 and the drain electrode 122 on the substrate 110. The active layer 131 may cover the source electrode 121 and the drain electrode 122. The active layer 131 may be formed by forming an organic semiconductor copolymer layer, an inorganic semiconductor copolymer layer or a semiconductor monomolecular layer on the substrate through a spin coating, an inkjet printing or a vacuum evaporation.

The organic dielectric layer 141 may be formed on the active layer 131. Referring to FIG. 4, the forming of the organic dielectric layer 141 may include: forming a composition for an organic dielectric layer; and heat-treating the composition (S204), wherein the forming of the composition includes: forming a diblock copolymer by using a hydrophilic copolymer with a hydrophilic group and a hydrophobic copolymer with a hydrophobic group (S201); attaching an adjacent nano precursor to the hydrophilic group (S202); and oxidizing or reducing the precursor (S203).

In operation S201, the diblock copolymer is formed by dissolving the hydrophilic copolymer and the hydrophobic copolymer in a solvent. In an embodiment, the solvent may be selected from a group of nonpolar organic solvents including toluene and xylene. The hydrophilic copolymer and the hydrophobic copolymer dissolved in the solvent may have a volume ratio expressed by 0.05<m/(m+n)<0.65, where m is the volume ratio of the hydrophilic copolymer, n is the volume ratio of the hydrophobic copolymer and m+n=1.

The hydrophilic copolymer may be at least one selected from the group consisting of poly(4-vinyl phenol), poly(2-vinylpyridine), polyacrylonitrile, polychloroprene, poly(vinylidene fluoride) and poly(vinylidene chloride). The hydrophilic copolymer has an average molecular weight ranging from 10000 to 100000.

The hydrophobic copolymer may be at least one selected from the group consisting of polybutadiene, polystyrene, polyisobutylene, poly(methyl methacrylate), polycarbonate, polychlorotrifluoroethylene), polyethylene, polypropylene, polytetrafluoroethylene (Teflon), CYTOP™ and polypropylene-co-butene. The hydrophobic copolymer has an average molecular weight ranging from 10000 to 100000.

The diblock copolymers may be arranged to form a predetermined group in a solution including the solvent. For example, the diblock copolymers may be arranged in a micelle, rod or lamella structure in the solvent. For this purpose, the amount of the diblock copolymer and the solvent may be adjusted such that the concentration of the diblock copolymer in a solution including the diblock copolymer and a solvent is equal to or more than the critical micelle concentration. The diblock copolymers may be arranged such that either the hydrophilic group or the hydrophobic group is directed toward a core of the group.

Such an arrangement of the diblock copolymers may be due to the amphiphilic character of the diblock copolymer. Specifically, since any one of the groups constituting the diblock copolymer has affinity to the solvent, it is arranged toward the solvent, whereas since the other group does not have affinity to the solvent, it may be arranged in a direction not adjacent to the solvent.

In an embodiment, when the solvent is a nonpolar organic solvent, the diblock copolymers may be arranged such that the hydrophilic groups are directed toward a core of the group of the diblock copolymers. For example, when the group of the diblock copolymers is arranged in a micelle structure, the hydrophilic groups may be arranged toward a core of the micelle structure. By the arrangement of the hydrophilic groups, the hydrophobic groups are directed toward a direction opposite to the core, i.e., toward the solvent. In other embodiment, when the group of the diblock copolymers is arranged in a rod form, the hydrophilic groups of the diblock copolymers may be arranged toward a core axis formed in a length direction of the rod form. By the arrangement of the hydrophilic groups, the hydrophobic groups may be arranged in a direction opposite to the core axis of the rod form, i.e., toward the solvent. Also, when the diblock copolymers are arranged in a lamella structure, the hydrophilic groups may be arranged toward a core of the lamella structure. By the arrangement of the hydrophilic groups, the hydrophobic groups may be arranged toward the solvent.

Nano-precursor is added to the solvent in which the diblock copolymer is dissolved. The nano-precursor may be attached to either the hydrophilic group or the hydrophobic group of the diblock copolymer (S202). The nano-precursor may be a precursor of a material that can trap charge. Also, the nano-precursor may be in an ion state. For example, the nano-precursor may be counter ion a metal ion or a metal compound ion. The nano-precusor may be added to the solvent with a counter ion of the metal ion or the metal compound.

In an embodiment, the nano-precursor may be attached to the hydrophilic group of the diblock copolymer. The nano-precursor may be arranged at a core of the group composed of the diblock copolymers. This is due to the fact that both the hydrophilic groups of the hydrophilic polymer and the nano-precursor have polarity.

As the nano-precursor is attached to the hydrophilic group, the solubility of the nano-precursor in the solution can be improved. In the case that the nano-precursor and the counter ion of the nano-precursor are provided in a nonpolar solvent, the solubility of the nano-precursor to the solvent can be remarkably decreased. As a result, nano-precursors that are not dissolved may be aggregated. Accordingly, the insulation characteristic of the organic dielectric layer formed by using the nano-precursor can be remarkably decreased.

However, as in the embodiments of the present invention, when the nano-precursors are provided in a solution including the diblock copolymers with hydrophilic groups and hydrophobic groups and a solvent, the insulation characteristic of the organic dielectric layer can be highly improved. In an embodiment, in the case when the nano-precursors are in an ion state, the nano-precursors have affinity to the hydrophilic group in the diblock copolymer. Accordingly, the nano-precursors can be dissolved in the solvent and properly dispersed in the solution. Accordingly, since nanoparticles formed by the nano-precursors are not aggregated in the composition for the organic dielectric layer, the insulation characteristic of the organic dielectric layer to be formed later can be enhanced.

An oxidant or reductant may be added to the solution (S203). The nano-precursors are oxidized or reduced by the oxidant or reductant, so that nanoparticles 143 may be formed. The nanoparticle 143 formed as above is a neutral atom or neutral molecule. Unlike this, the nanoparticle 143 may be in an ion state. The nanoparticle 143 may be surrounded by the diblock copolymer. By the above procedures, the composition for the organic dielectric layer including the diblock copolymer and the nanoparticles can be formed.

The composition for the organic dielectric layer formed as above may be deposited on the active layer 131. The composition may be deposited on the active layer 131 by a spin coating.

Thereafter, a heat treatment process may be performed (S204). By the heat treatment process, the organic dielectric layer 141 may be formed. The heat treatment process may be performed at a temperature equal to or higher than glass transition temperature Tg.

By the heat treatment process, the hydrophilic polymer 145 and the hydrophobic polymer 147 may be phase-separated. The group of the hydrophilic polymers 145 and the nanoparticles 143 surrounded by the hydrophilic polymers 145 may be arranged at a core in the organic dielectric layer 141. The hydrophobic polymer 147 may be arranged an outer region in the organic dielectric layer 141. That is, the nanoparticles 143 and the hydrophilic polymers 145 surrounding the nanoparticles 143 move to the core of the organic dielectric layer 141 by self-assembly of the hydrophilic polymer 143 and the hydrophobic polymer 147, and the hydrophobic polymers 147 move to the outer region in the organic dielectric layer 141.

The methods of forming an organic dielectric layer according to embodiments of the present invention can enhance the process efficiency. As aforementioned, the organic dielectric layer 141 may be formed by coating a composition for the organic dielectric layer on the active layer 131 and heat-treating the composition. The organic dielectric layer 141 formed as above may have a charge storage part that can store charges, and the insulation part surrounding the charge storage part such that the charges are not connected to external conductive elements. To form a layer having both the charge storage part and the insulation part, a process of forming a charge storage material layer and processes of forming a plurality of dielectric layers for insulating the charge storage material layer from other electrical elements should be performed. However, by the methods of forming an organic dielectric layer according to embodiments of the present invention, it is possible to form a layer having both the charge storage part and the insulation part through minimized processes. Accordingly, the process efficiency can be enhanced.

The gate electrode 151 may be formed on the organic dielectric layer 141. The gate electrode 151 may be formed by depositing a conductive layer on the organic dielectric layer 141 and patterning the conductive layer.

Hereinafter, methods of fabricating the aforementioned composition for organic dielectric layer will be described in detail. The following methods are exemplarily provided to realize the technical spirit of the present invention.

A solution for dielectric layer was prepared by dissolving a diblock copolymer including a hydrophilic polymer including a hydrophilic group and a hydrophobic polymer including a hydrophobic group in a solvent. In this embodiment, the solvent was selected from the group of nonpolar organic solvents including toluene and xylene. While the hydrophilic polymer and the hydrophobic polymer were selected from various polymers, poly(2-vinyl pyridine) with an average molecular weight of about 10,000 was used as the hydrophilic polymer and polystyrene with an average molecular weight of about 55,000 was used as the hydrophobic polymer, in this embodiment. The polymers were completely dissolved in the solvent to prepare a solution, and the prepared solution was filtered to remove an impurity remaining therein. The diblock copolymer formed according to the present embodiment is expressed by the below chemical formula 1. Unlike this, in the case where poly(4-vinyl pyridine) is used as the hydrophilic polymer, a diblock copolymer expressed by the below chemical formula 2 may be formed. In chemical formulas 1 and 2, n is the volume ratio of the hydrophobic polymer constituting the diblock copolymer, m is the volume ratio of the hydrophilic polymer, and n+m=1.

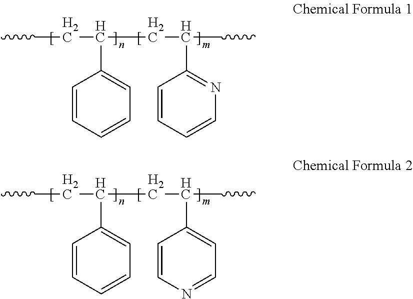

The concentration of the diblock copolymer in the solution may be equal to or higher than the critical micelle concentration. The diblock copolymers may be arranged in a group. For example, the diblock copolymers may be arranged in a micelle, rod or lamella structure. The volume ratio of the hydrophilic polymer with the hydrophilic group in the diblock copolymer may be 0.05-0.65.

The hydrophobic groups of the diblock copolymers may be arranged toward an edge of a group of the diblock copolymers. This phenomenon is due to the characteristics that a repulsive force acts between a portion including the hydrophilic group and a portion including the hydrophobic group, and the portion including the hydrophilic group and the portion including the hydrophobic group minimize an interfacial area therebetween. Accordingly, the hydrophilic polymers are directed toward a core of the group. In an embodiment, when the diblock copolymers are arranged in a micelle structure, the hydrophilic groups of the diblock copolymers may be directed toward a core of the micelle structure.

Nano-precursor was added to the solution including the diblock copolymer. The nano-precursor may include a nanoparticle existing in an ionized state. The nano-precursor may be provided in the solution in an ionic bond state with an counter ion of the nano-precursor. In this embodiment, tetrachloroauric acid (HAuCl₄.3H₂O) was added to the solution. Tetrachloroauric acid (HAuCl₄.3H₂O) is a compound of Au ion (Au³⁺) (that is a nano-precursor) and counter ions thereof. The nano-precursor may be attached to the hydrophilic group of the hydrophilic polymer. The nano-precursor may be attached to the hydrophilic group of the hydrophilic polymer alone or in combination with counter ion. By such an attachment, a nanoparticle-hydrophilic polymer unit may be formed. The added amount of the nano-precursor may be adjusted such that the mole concentration of the nanoparticle-hydrophilic polymer unit is 0.1-0.3.

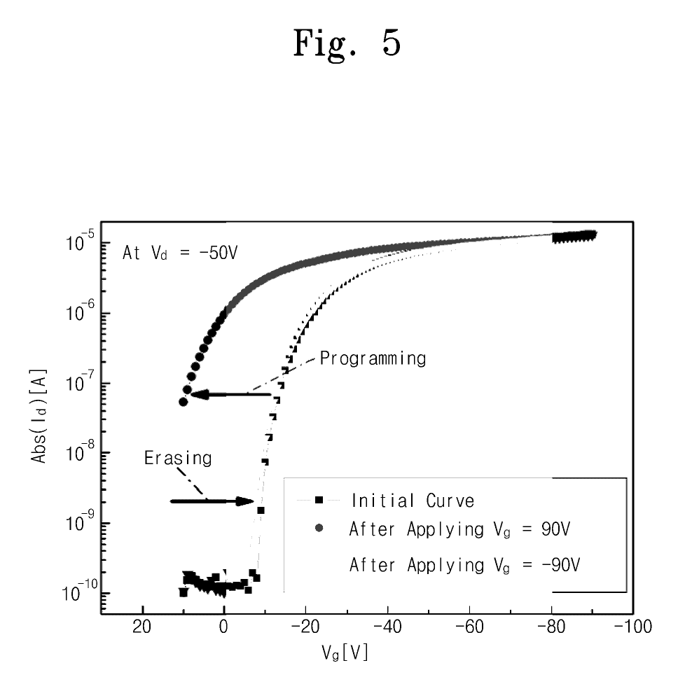

Hereinafter, effects according to the embodiments of the present invention will be described with reference to FIG. 5. FIG. 5 is a graph illustrating current-voltage characteristic of the organic thin film transistor shown in FIGS. 1A and 1B. In the graph, x-axis represents gate voltage (Vg) and y-axis represents drain current (Id). The organic dielectric layer 141 of the organic thin film transistor is formed by using the composition for organic dielectric layer, which is prepared by the above-described method. In this embodiment, a PMOS transistor is used.

In a program operation, a drain voltage (Vd) is applied between the source electrode 121 and the drain electrode 122. As the drain voltage (Vd) is applied, charges proportional to the drain voltage (Vd) flow through the active layer 131. A gate voltage (Vg) is applied to the gate electrode 151. The gate voltage (Vg) may be a positive voltage. In this embodiment, the gate voltage (Vg) of 90 V is applied to the gate electrode 151. As the gate voltage (Vg) is applied, charges in the active layer 131 tunnel through the insulation part of the organic dielectric layer 141 and may be trapped in the charge storage part of the organic dielectric layer 141. In this embodiment, the charge may be electron. As aforementioned, the insulation part of the organic dielectric layer 141 may include the hydrophobic polymer and the charge storage part of the organic dielectric layer 141 may include nanoparticles 143 and the hydrophilic polymer surrounding the nanoparticles 143. As the charges are trapped in the charge storage part, data is stored in a cell including the organic thin film transistor. At this time, when a voltage is applied to the source/drain electrodes 121, 122, a relatively high current flows between the source electrode 121 and the drain electrode 122 (see -- of FIG. 5).

In an erase operation, a negative voltage is applied to the gate electrode 151. In this embodiment, −90 V is applied to the gate electrode 151. In this case, the charges stored in the charge storage part of the organic dielectric layer 141 can move again to the active layer 131. By the movement of the charges to the active layer 131, data of a cell including the organic thin film transistor can be erased. At this time, when a voltage is applied to the source/drain electrodes 121, 122, a relatively high current flows between the source electrode 121 and the drain electrode 122 (see -▾- of FIG. 5).

From the graph of FIG. 5, it can be seen that the organic thin film transistor according to the embodiments of the present invention has a current-voltage characteristic suitable for operation of a transistor.

According to embodiments of the present invention, organic thin film transistors can be formed by more simplified process. Also, the organic thin film transistors formed according to embodiments of the present invention may include an organic dielectric layer with superior insulation characteristics. Accordingly, organic thin film transistors with enhanced reliability can be provided.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A method of manufacturing an organic thin film transistor, the method comprising:
forming a source electrode and a drain electrode on a substrate;
forming an active layer on the substrate between the source electrode and the drain electrode;
forming a gate electrode on a surface of the active layer; and
forming an organic dielectric layer between the active layer and the gate electrode,
wherein the forming of the organic dielectric layer includes providing a composition for organic dielectric layer including a diblock copolymer composed of hydrophilic polymers with hydrophilic groups and hydrophobic polymers with hydrophobic groups.

2. The method of claim 1, wherein the composition for organic dielectric layer further comprises:
nano-precursors adjacent to a first group selected from the hydrophilic groups and the hydrophobic groups of the diblock copolymer; and
a solvent having affinity to a second group selected from the hydrophilic groups and the hydrophobic groups of the diblock copolymer.

3. The method of claim 2, wherein the first group is the hydrophilic group and the second group is the hydrophobic group.

4. The method of claim 2, wherein the forming of the organic dielectric layer further comprises oxidizing or reducing the nano-precursors.

5. The method of claim 2, wherein the forming of the organic dielectric layer comprises self-assembly of the hydrophilic polymers and the hydrophobic polymers of the diblock copolymer.

6. The method of claim 5, wherein the nano-precursors are surrounded by the self-assembled hydrophilic polymers.

7. The method of claim 1, wherein the concentration of the diblock copolymers in the composition for organic dielectric layer is equal to or higher than the critical micelle concentration.

8. The method of claim 1, wherein the hydrophilic polymers in the diblock copolymer has a volume ratio equal to or more than 0.05 and equal to or less than 0.65.

9. The method of claim 1, further comprising providing a temperature equal to or higher than the glass transition temperature to the composition for organic dielectric layer.
